(19) United States
(12) Patent Application Publication
(10) Pub. No.: US 2009/0072291 A1
(43) Pub. Date: Mar. 19, 2009

(54) SEMICONDUCTOR MEMORY DEVICE

(75) Inventor: Yoshihiro TAKAISHI, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: Elpida Memory, Inc., Tokyo (JP)

(21) Appl. No.: 12/212,364

(22) Filed: Sep. 17, 2008

(30) Foreign Application Priority Data
Sep. 18, 2007 (JP) 2007-241048

(51) Int. Cl. H01L 27/108

(52) U.S. Cl. 257/306; 257/E27.086

(57) ABSTRACT

A semiconductor memory device includes: first word lines; second word lines, each of the second word lines being electrically connected to a corresponding one of the first word lines; bit lines; and memory cells, each of the memory cells including a transistor and a capacitor. The semiconductor memory device includes: a first cell array portion in which the memory cells are arrayed; and a second cell array portion in which dummy cells, the first word lines and the bit lines are located in the same layout as the first cell array portion. In the second cell array portion, conductive plugs are provided, each of the conductive plugs connecting one of the first word lines and a corresponding one of the second word lines.

### BACKGROUND OF THE INVENTION

1. Field of the Invention

The present invention relates to a semiconductor memory device.

2. Description of Related Art

Conventionally, a transistor-miniaturizing technique has been used mainly in order to cope with the high integration of a semiconductor memory device. Recently, it has become difficult to miniaturize transistors any further as the demand for high integration grows. For example, if the gate length L of a cell transistor in a DRAM (Dynamic Random Access Memory) becomes extremely short, the short channel effect of the cell transistor becomes increasingly significant. Consequently, it becomes difficult to control a threshold voltage. In addition, the S value of the cell transistor increases and, from the viewpoint of reduction in the off-state current of the transistor, there arises the need for an even higher threshold voltage.

Means for shallowing the source and drain diffusion layers of a transistor is available as means for reducing the short channel effect. However, the means has the problem of increasing the junction leakage of a cell transistor in a DRAM, thus degrading the refresh characteristics of the DRAM.

In recent years, a study is being made of a transistor having a three-dimensional structure (hereinafter referred to as a “vertical transistor”) as the transistor-miniaturizing technique.

FIG. 9 shows one example of the vertical transistor disclosed in Japanese Patent Laid-Open No. 5-136374 (Patent Document 1). In the figure, reference numeral 101 denotes a silicon substrate, reference numeral 102 denotes a gate electrode, reference numeral 103 denotes a drain region, reference numeral 104 denotes a source region, reference numeral 105 denotes a gate insulating film, reference numeral 106 denotes a source electrode, reference numeral 107 denotes an insulating film, reference numeral 108 denotes an insulating film, reference numeral 109 denotes a drain electrode, reference numeral 110 denotes a channel stopper, and reference numeral 111 denotes a field insulating film.

This vertical transistor has a columnar silicon region extending in a vertical direction with respect to the principal surface of a semiconductor substrate, and a channel is formed along the side surface of this columnar silicon region. The occupation area of this vertical transistor is small, and the area does not increase even if a channel length (gate length) is increased. Accordingly, it is possible to suppress the short channel effect without having to increase the occupation area of the transistor. The vertical transistor also has the advantage of being able to completely deplete the channel portion and, thereby, obtain an excellent S value and a large drain current. The minimum cell area of a DRAM using a planar transistor as its cell transistor is generally 8F² in the case of a folded bit line cell and 6F² in the case of an open bit line cell for the minimum half pitch of F. In contrast, the cell area of a DRAM using this vertical transistor as its cell transistor can be as small as even the highest-density layout area of 4F².

However, as a problem when the vertical transistor is used as a cell transistor, there is mentioned an increase in word-line resistance. Since a gate electrode for composing a word line is formed on the side surface of a columnar silicon region, the film thickness of the gate electrode can only be set to less than half a spacing between mutually adjacent columnar silicon regions. In addition, since the gate electrode needs to be formed on a surface of three-dimensional (columnar) silicon, a material having an excellent coverage property is required. Furthermore, it is difficult to form a laminated structure composed of polysilicon and a metal material, which is a gate electrode structure common in the planar structure, in a DRAM cell which uses such a vertical transistor as described above. Consequently, there is formed a word line composed of a single layer of polysilicon and having a small film thickness, thus increasing the value of word-line resistance by a factor of several tens, compared with that of a structure in which a conventional planar transistor is used.

If the word-line resistance increases, the DRAM cannot operate normally any longer unless any measures are taken and, therefore, there arises the need for a measure to decrease the number of cells to be connected to the word line. However, this measure results in an increase in the number of driver circuits for driving the word line, thereby greatly increasing the cell area. As an alternative measure, there is a method for layering word lines into a hierarchical structure, thereby reducing the resistance thereof. According to this method, it is possible to reduce the resistance of a word line itself and, therefore, there is no need to increase the number of a really-large driver circuits. However, this method requires a region for electrically connecting the upper-layer and lower-layer word lines of the hierarchical structure and, therefore, the cell area increases unavoidably.

### SUMMARY

The present invention seeks to solve one or more of the above problems, or to improve upon those problems at least in part.

In one embodiment, there is provided a semiconductor memory device, including:
first word lines located along a first direction;
second word lines provided along the first direction on the upper-layer side of the first word lines, each of the second word lines being electrically connected to a corresponding one of the first word lines;
bit lines located along a second direction intersecting with the first direction; and
memory cells located at intersections of the first word lines and the bit lines, each of the memory cells including a capacitor and a transistor containing a source connected to the capacitor, a gate connected to one of the first word lines, and a drain connected to one of the bit lines;
wherein the transistor includes:
   a semiconductor pillar protruding upwardly with respect to a principal surface of a semiconductor substrate;
   a gate insulating film formed on a side surface of the semiconductor pillar;
   a gate electrode formed so as to cover the side surface of the semiconductor pillar through the gate insulating film;
   an upper diffusion layer formed in a upper portion of the semiconductor pillar; and
   a lower diffusion layer formed in a part of the semiconductor substrate below the side surface of the semiconductor pillar;
the capacitor is provided immediately above the semiconductor pillar of the corresponding transistor, the capacitor including an upper electrode, a dielectric film and a lower electrode connected to the upper diffusion layer of the semiconductor pillar through a first conductive plug; and
the semiconductor memory device includes:
   a first cell array portion wherein first cells are arrayed, each of the first cells including the transistor and the capacitor; and
   a second cell array portion wherein second cells, the first word lines and the bit lines are located in the same layout as the first cell array portion, each of the second cells including the same transistor structure containing a semiconductor pillar, a gate insulating film and a gate electrode as the first cells, and including the same capacitor structure containing a lower electrode, a dielectric film and an upper electrode as the first cells, and wherein second conductive plugs are provided, each of the second conductive plugs connecting one of the first word lines and a corresponding one of the second word lines.

In another embodiment, an insulating film can be interposed between the semiconductor pillars and the lower electrodes within the second cells such that the second cells do not operate as memory cells.

In another embodiment, each of the second conductive plugs can extend across two or more of the second cells located along the first direction in the second cell array portion.

In another embodiment, each of the second conductive plugs can be located such that the second conductive plug overlaps with a corresponding one of the semiconductor pillars in the second cell array portion.

In another embodiment, each of the second word lines can be located on the lower-layer side of the capacitors such that the second word line passes through between the first conductive plugs of the first cells adjacent to each other in the second direction.

In another embodiment, the first word lines can be formed of an impurity-containing polysilicon, and the second word lines can be formed of a metal-containing material having a resistivity lower than that of the first word lines.

In another embodiment, the bit lines can intersect with the first word lines on the lower-layer side of the first word lines.

In another embodiment, there is provided a semiconductor memory device, including:
first word lines located along a first direction;
second word lines provided along the first direction above the first word lines, each of the second word lines being electrically connected to a corresponding one of the first word lines;
bit lines; and
cells located at intersections of the first word lines and the bit lines, each of cells including a transistor structure and a capacitor structure;
wherein the semiconductor memory device includes:
a first cell array portion wherein each of the cells is formed such that the cell is a memory cell; and
a second cell array portion wherein the transistor structure is insulated from the capacitor structure in each of the cells such that the cell is a dummy cell, and wherein conductive plugs are provided, each of the conductive plugs connecting one of the first word lines and a corresponding one of the second word lines.

In another embodiment, there is provided a semiconductor memory device, including:
a vertical transistors disposed at a memory cell portion and a word-shunt portion;
first word lines connected to each of the vertical transistors at the memory cell portion and the word-shunt portion; and
second word lines disposed at the memory cell portion and the word-shunt portion, provided along the direction of the first word lines, each of the second word lines being electrically connected to a associating one of the first word lines at the word-shunt portion.

According to the present invention, it is possible to provide a highly integrated semiconductor memory device, while still maintaining the satisfactory operation thereof.

### BRIEF DESCRIPTION OF THE DRAWINGS

The features and advantages of the embodiments will be more apparent from the following description of certain preferred embodiments taken in conjunction with the accompanying drawings, in which:

FIG. 1 is a plan view used to explain a cell layout in one exemplary embodiment of a semiconductor memory device according to the present invention;

FIG. 2 is a cross-sectional view (taken along the line X1-X1 of FIG. 1) used to explain an exemplary embodiment of the present invention;

FIG. 3 is a cross-sectional view (taken along the line X2-X2 of FIG. 1) used to explain an exemplary embodiment of the present invention;

FIG. 4 is a cross-sectional view (taken along the line Y1-Y1 of FIG. 1) used to explain an exemplary embodiment of the present invention;

FIG. 5 is a cross-sectional view (taken along the line Y2-Y2 of FIG. 1) used to explain an exemplary embodiment of the present invention;

FIG. 6A is a cross-sectional view used to explain one step in a manufacturing method according to an exemplary embodiment of the present invention;

FIG. 6B is a cross-sectional view used to explain a step following the step of FIG. 6A in a manufacturing method according to an exemplary embodiment of the present invention;

FIG. 6C is a cross-sectional view used to explain a step following the step of FIG. 6B in a manufacturing method according to an exemplary embodiment of the present invention;

FIG. 6D is a cross-sectional view used to explain a step following the step of FIG. 6C in a manufacturing method according to an exemplary embodiment of the present invention;

FIG. 6E is a cross-sectional view used to explain a step following the step of FIG. 6D in a manufacturing method according to an exemplary embodiment of the present invention;

FIG. 6F is a cross-sectional view used to explain a step following the step of FIG. 6E in a manufacturing method according to an exemplary embodiment of the present invention;

FIG. 6G is a cross-sectional view used to explain a step following the step of FIG. 6F in a manufacturing method according to an exemplary embodiment of the present invention;

FIG. 6H is a cross-sectional view used to explain a step following the step of FIG. 6G in a manufacturing method according to an exemplary embodiment of the present invention;

FIG. 6I is a cross-sectional view used to explain a step following the step of FIG. 6H in a manufacturing method according to an exemplary embodiment of the present invention;

FIG. 6J is a cross-sectional view used to explain a step following the step of FIG. 6I in a manufacturing method according to an exemplary embodiment of the present invention;

FIG. 6K is a cross-sectional view used to explain a step following the step of FIG. 6J in a manufacturing method according to an exemplary embodiment of the present invention;

FIG. 6L is a cross-sectional view used to explain a step following the step of FIG. 6K in a manufacturing method according to an exemplary embodiment of the present invention;

FIG. 6M is a cross-sectional view used to explain a step following the step of FIG. 6L in a manufacturing method according to an exemplary embodiment of the present invention;

FIG. 6N is a cross-sectional view used to explain a step following the step of FIG. 6M in a manufacturing method according to an exemplary embodiment of the present invention;

FIG. 6O is a cross-sectional view used to explain a step following the step of FIG. 6N in a manufacturing method according to an exemplary embodiment of the present invention;

FIG. 6P is a cross-sectional view used to explain a step following the step of FIG. 6O in a manufacturing method according to an exemplary embodiment of the present invention;

FIG. 6Q is a cross-sectional view used to explain a step following the step of FIG. 6P in a manufacturing method according to an exemplary embodiment of the present invention;

FIG. 6R is a cross-sectional view used to explain a step following the step of FIG. 6Q in a manufacturing method according to an exemplary embodiment of the present invention;

FIG. 6S is a cross-sectional view used to explain a step following the step of FIG. 6R in a manufacturing method according to an exemplary embodiment of the present invention;

FIG. 6T is a cross-sectional view used to explain a step following the step of FIG. 6S in a manufacturing method according to an exemplary embodiment of the present invention;

FIG. 7I is a cross-sectional view used to explain one step in a manufacturing method according to an exemplary embodiment of the present invention;

FIG. 7J is a cross-sectional view used to explain a step following the step of FIG. 7I in a manufacturing method according to an exemplary embodiment of the present invention;

FIG. 7K is a cross-sectional view used to explain a step following the step of FIG. 7J in a manufacturing method according to an exemplary embodiment of the present invention;

FIG. 7L is a cross-sectional view used to explain a step following the step of FIG. 7K in a manufacturing method according to an exemplary embodiment of the present invention;

FIG. 7M is a cross-sectional view used to explain a step following the step of FIG. 7L in a manufacturing method according to an exemplary embodiment of the present invention;

FIG. 7N is a cross-sectional view used to explain a step following the step of FIG. 7M in a manufacturing method according to an exemplary embodiment of the present invention;

FIG. 7O is a cross-sectional view used to explain a step following the step of FIG. 7N in a manufacturing method according to an exemplary embodiment of the present invention;

FIG. 7P is a cross-sectional view used to explain a step following the step of FIG. 7O in a manufacturing method according to an exemplary embodiment of the present invention;

FIG. 7Q is a cross-sectional view used to explain a step following the step of FIG. 7P in a manufacturing method according to an exemplary embodiment of the present invention;

FIG. 7R is a cross-sectional view used to explain a step following the step of FIG. 7Q in a manufacturing method according to an exemplary embodiment of the present invention;

FIG. 7S is a cross-sectional view used to explain a step following the step of FIG. 7R in a manufacturing method according to an exemplary embodiment of the present invention;

FIG. 7T is a cross-sectional view used to explain a step following the step of FIG. 7S in a manufacturing method according to an exemplary embodiment of the present invention;

FIG. 8 is a plan view used to explain a cell layout in a reference example; and

FIG. 9 is a schematic view used to explain the structure of a conventional vertical transistor.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

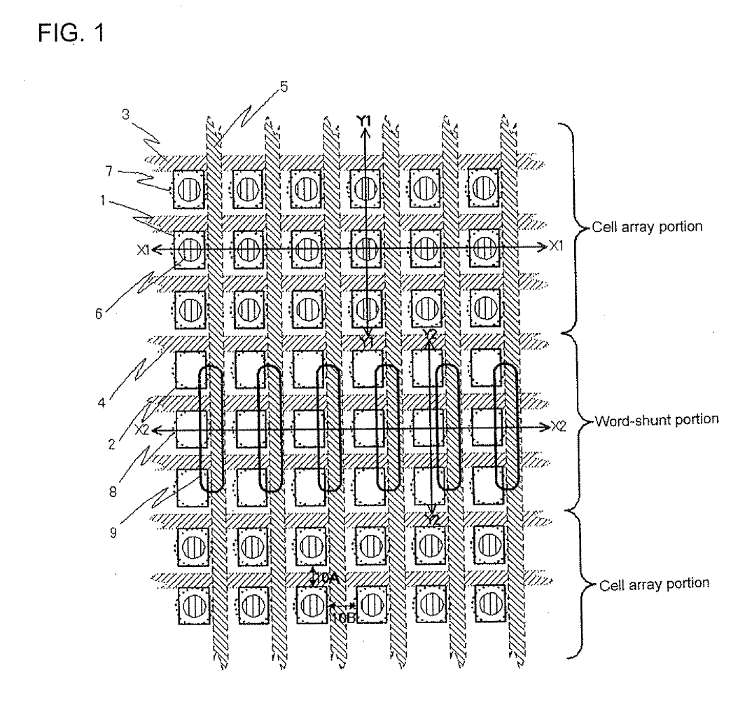

Referring to FIG. 1, a semiconductor device according to a first embodiment of the present invention applied to a DRAM will be described.

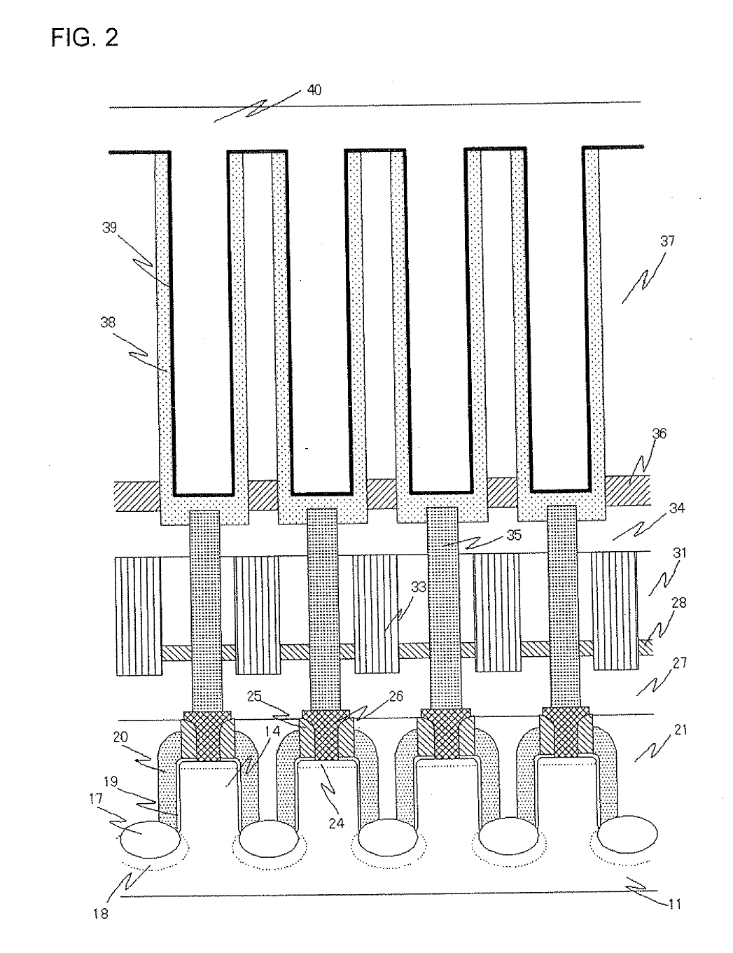

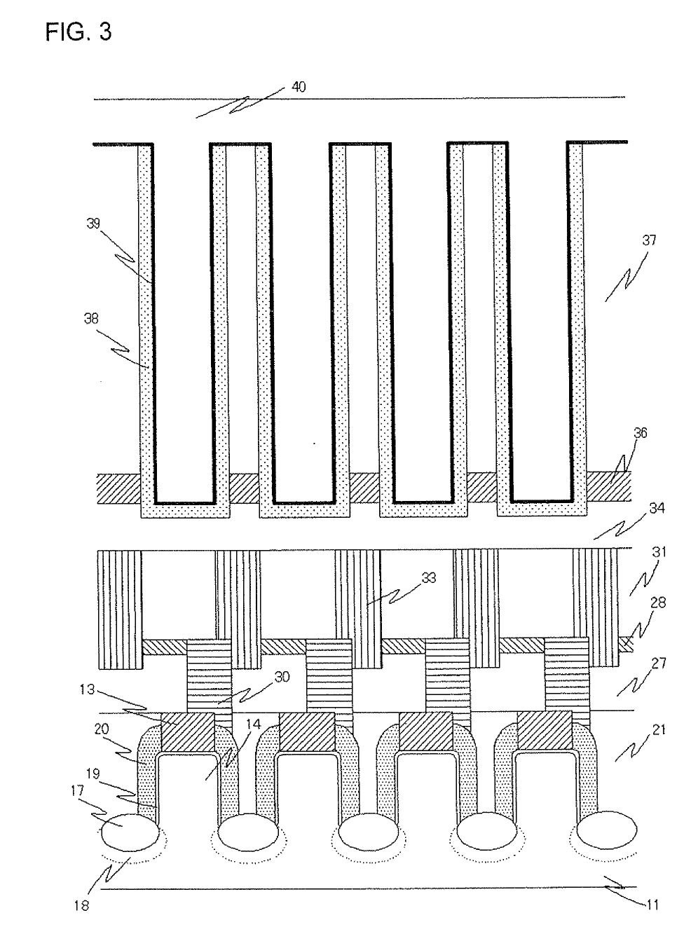

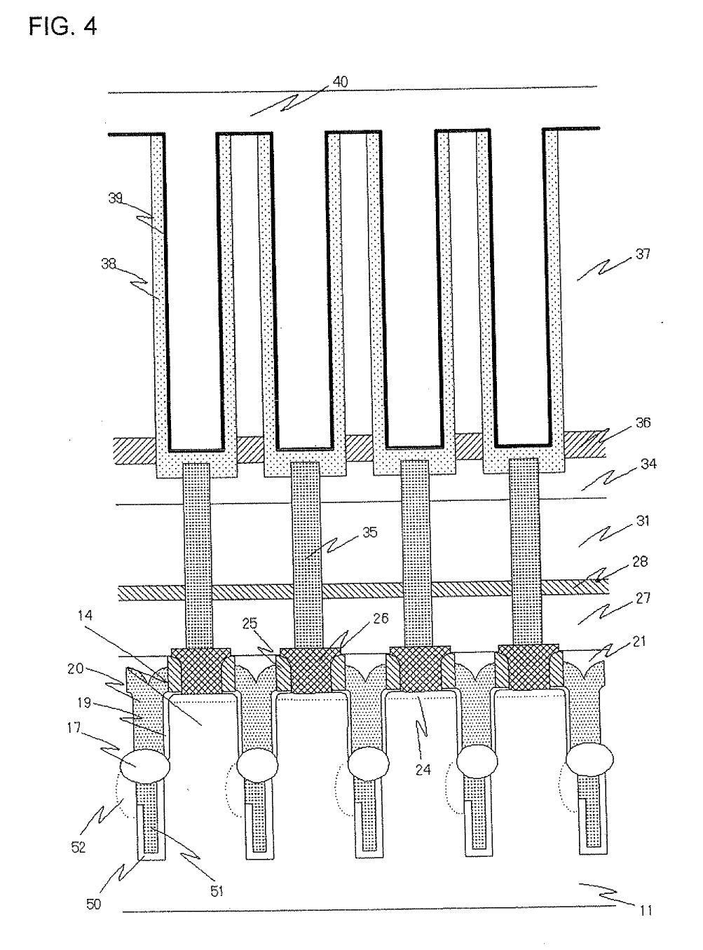

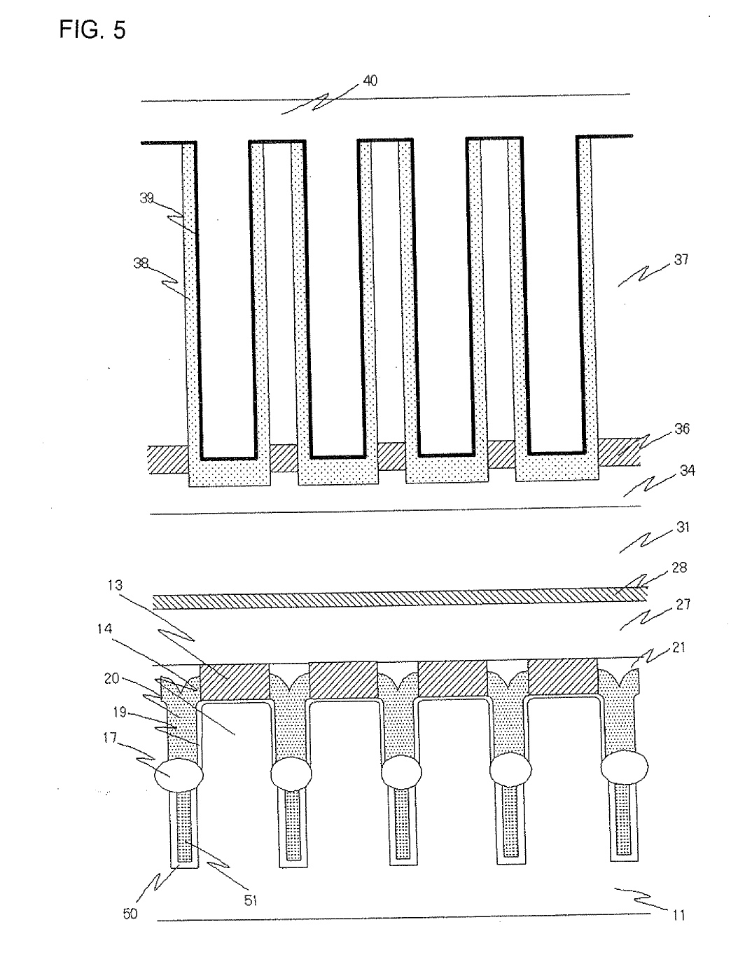

FIG. 1 illustrates the layout (4F² cell layout) of a memory cell of the present exemplary embodiment; FIG. 2 illustrates the cross-section structure of a cell array portion as viewed along the line X1-X1 of FIG. 1; FIG. 3 illustrates the cross-section structure of a word-shunt portion as viewed along the line X2-X2 of FIG. 1; FIG. 4 illustrates the cross-section structure of a cell array portion as viewed along the line Y1-Y1 of FIG. 1; and FIG. 5 illustrates the cross-section structure of a word-shunt portion as viewed along the line Y2-Y2 of FIG. 1.

As shown in FIGS. 2 and 4, a cell transistor in the present exemplary embodiment includes a pillar 14 made of silicon (reference numeral 1 in FIG. 1), a gate insulating film 19 formed on the side surface of the pillar, a gate electrode (word line) 20 provided so as to cover the side surface of the pillar through this gate insulating film, an upper diffusion layer 24 formed in the upper portion of the pillar, and a lower diffusion layer 18 formed in a part of the silicon substrate near the lower portion of the side surface of the pillar. The lower diffusion layer 18 is electrically connected to a bit line 51 (reference numeral 3 in FIG. 1). The upper diffusion layer 24 is connected to a capacitive lower electrode 38 through a silicon plug 26 and a capacitive contact plug 35, and this capacitive lower electrode 38, a capacitive insulating film 39 and a capacitive upper electrode 40 form a cylindrical capacitor (reference numeral 7 in FIG. 1).

As shown in FIG. 1, the DRAM of the present exemplary embodiment includes a cell array portion in which memory cells containing the above-described cell transistor and a capacitor are arranged in a matrix and a word-shunt portion located between the cell array portions.

As shown in FIGS. 3 and 5, in the word-shunt portion, the DRAM includes a pillar 14 (reference numeral 2 in FIG. 1), a gate insulating film 19 formed on the side surface of the pillar, a gate electrode (word line) 20 provided so as to cover the side surface of the pillar through this gate insulating film, a lower diffusion layer 18 formed in a part of the silicon substrate near the lower portion of the side surface of the pillar, a cylindrical capacitor (reference numeral 8 in FIG. 1) formed of a capacitive lower electrode 38, a capacitive insulating film 39 and a capacitive upper electrode 40, and a bit line 51 (reference numeral 4 in FIG. 1), arranged in the same structure and layout as the cell array portion. In addition, there is formed a word-shunt contact plug 30 (reference numeral 9 in FIG. 1) for connecting a gate electrode 20 (word line) and a word-shunt interconnect 33 (reference numeral 5 in FIG. 1) extending above the gate electrode 20 in the longitudinal direction of the word line (in the direction of the line Y1-Y1 in FIG. 1). While the pitch of the word-shunt contact plug 30 is the same as that of a cell, it is possible, from the viewpoint of increasing a contact area and thereby reducing contact resistance, to form the word-shunt contact plug 30 into a vertically-long shape extending across a plurality of cells located along the longitudinal direction of the word lines. Also in the word-shunt portion, the word-shunt interconnect 33 is laid out into the same structure and at the same pitch as in the cell array portion. In the cell array portion, however, as shown in FIG. 2, the word-shunt interconnect 33 is located so as to pass through between the capacitive contact plugs 35 of memory cells adjacent to each other in the X1-X1 line direction of FIG. 1.

The capacitive contact plug 35 (reference numeral 6 in FIG. 1) and the silicon plug 26, which are provided in the cell array portion, are not provided in this word-shunt portion. On the other hand, as shown in FIG. 1, a pillar 2, a gate insulating film (not illustrated), a gate electrode (not illustrated), and a capacitor 8 are laid out in the same structure (shape, size and material) and at the same pitch as the pillar 1, the gate insulating film (not illustrated), the gate electrode (not illustrated) and the capacitor 7 of the cell array portion. Each word line (not illustrated in FIG. 1, but denoted by reference numeral 20 in FIGS. 2 to 5) constitutes the gate electrode of each of cells located along the longitudinal direction of the word line in the cell array portion and in the word-shunt portion. In the word-shunt portion, each bit line is laid out in the same structure (shape, size and material) and at the same pitch as in the cell array portion. The bit lines intersect with the word lines on the lower-layer side of the word lines.

As shown in FIGS. 1, 3 and 5, no capacitive contact plugs 35 are provided in the word-shunt portion. That is, the capacitive lower electrode 38 of the capacitor is not electrically connected to any other conductive portions. By taking advantage of the space thus produced, the word-shunt interconnect 33 (reference numeral 5 in FIG. 1) is connected to the word line 20 (gate electrode) through the word-shunt contact plug 30 (reference numeral 9 in FIG. 1), as shown in FIG. 3. In the present exemplary embodiment, as shown in FIG. 1, the word-shunt contact plug 9 is located so as to overlap with the pillar 2.

As described above, in the word-shunt portion, the upper layer-side word line (word-shunt interconnects 5 and 33) and the lower layer-side word line 20 are connected to each other through the word-shunt contact plug 30. In addition, dummy cells are provided in the same layout as the memory cells of the cell array portion, in order to avoid impairing the repeatability of memory cell disposition.

By forming word lines into a multilayer structure by providing the upper layer-side word line (word-shunt interconnects 5 and 33) and the lower layer-side word line 20, it is possible to reduce the resistance of the word lines. In addition, by making the layout of a portion in which the upper-layer word lines and lower-layer word lines are connected (word-shunt portion) identical to the layout of the cell array portion, there is no need to provide the dummy cells at the ends of the cell array portion and, therefore, it is possible to reduce the area of the DRAM.

By forming the lower-layer word lines using polysilicon having an excellent coverage property and forming the upper-layer word lines using a low-resistivity metal-containing material, it is possible to improve workability and further reduce the word-line resistance.

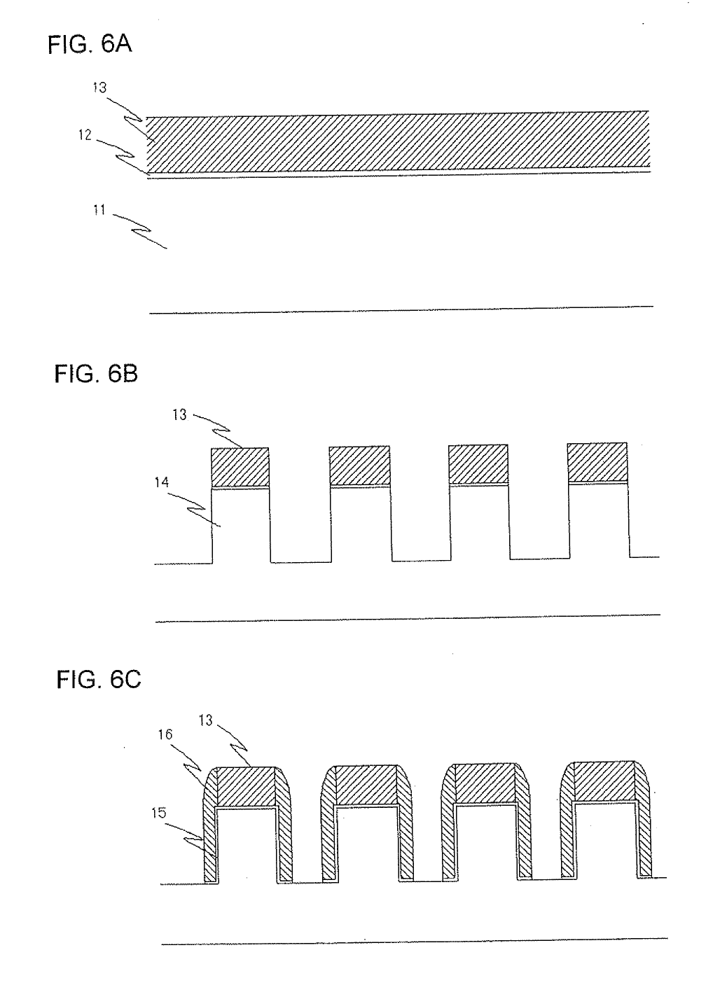

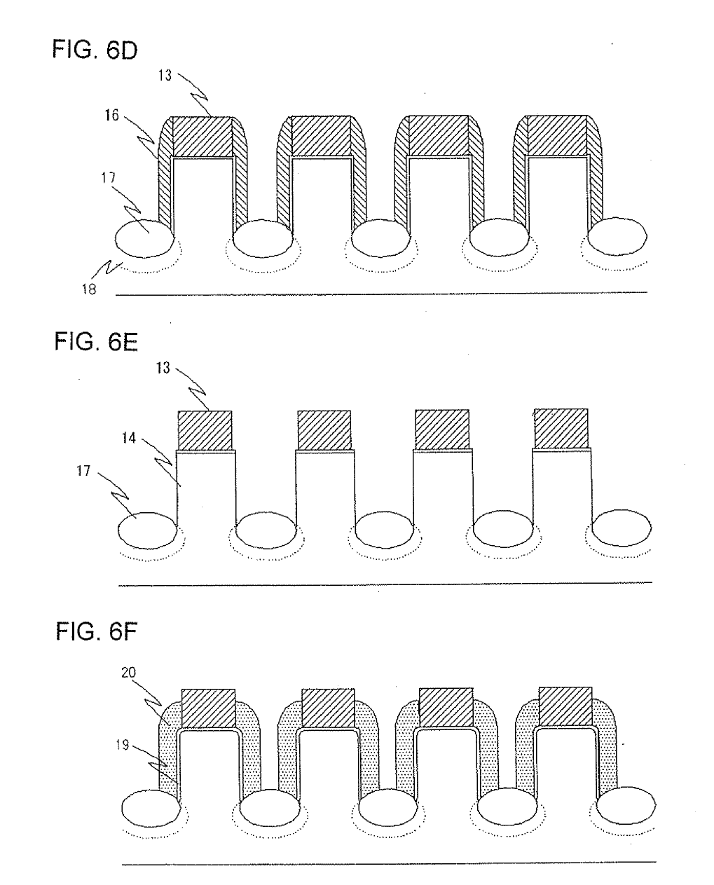

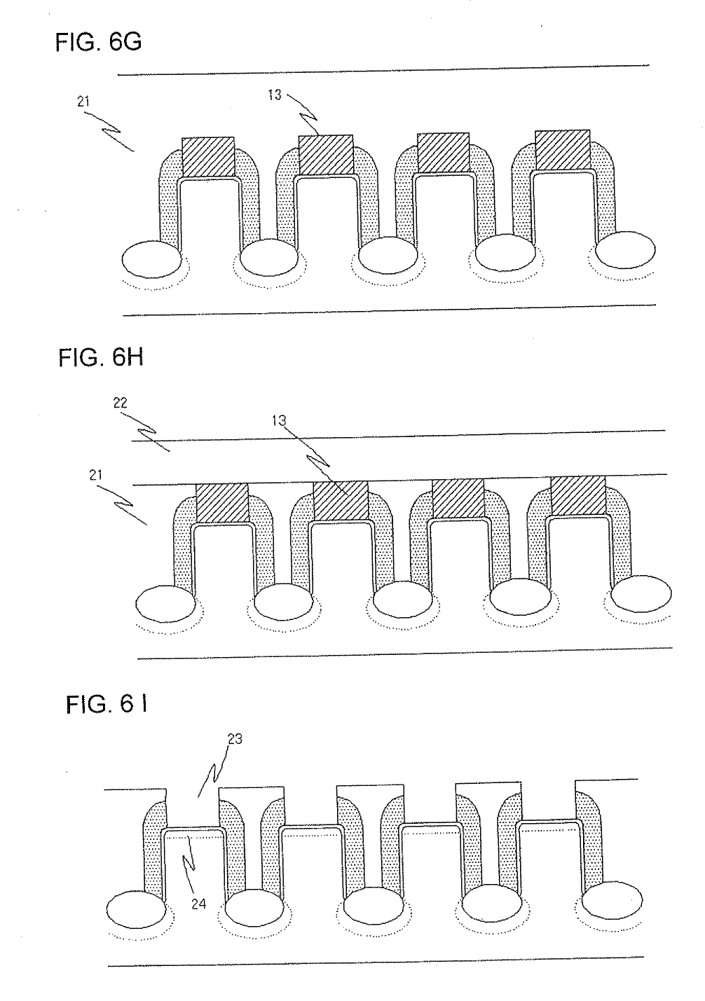

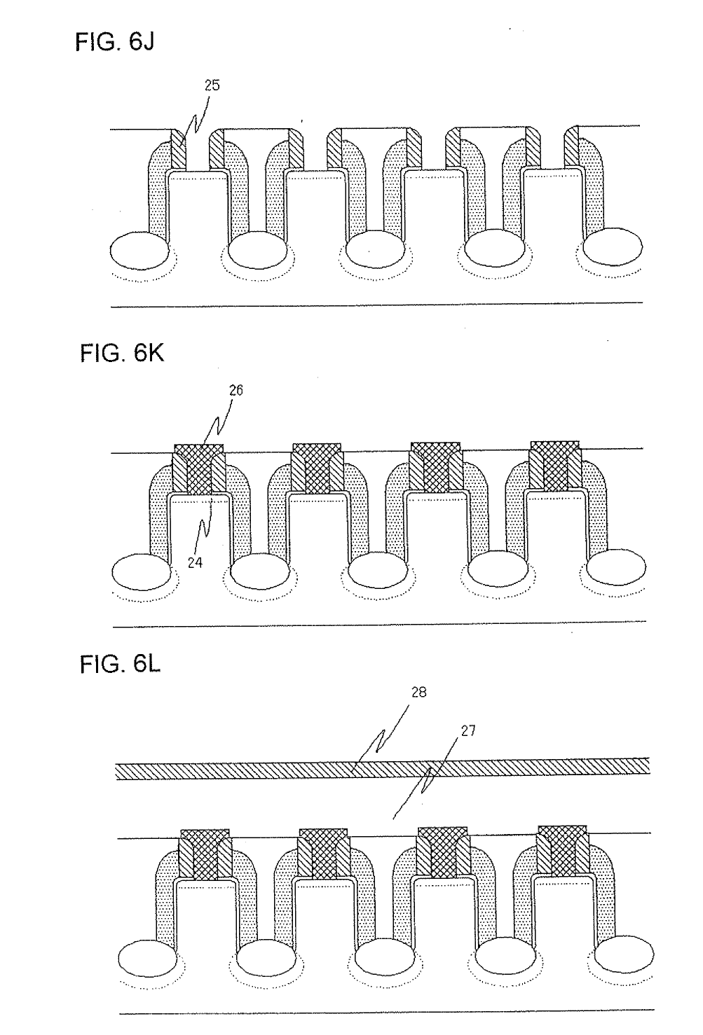

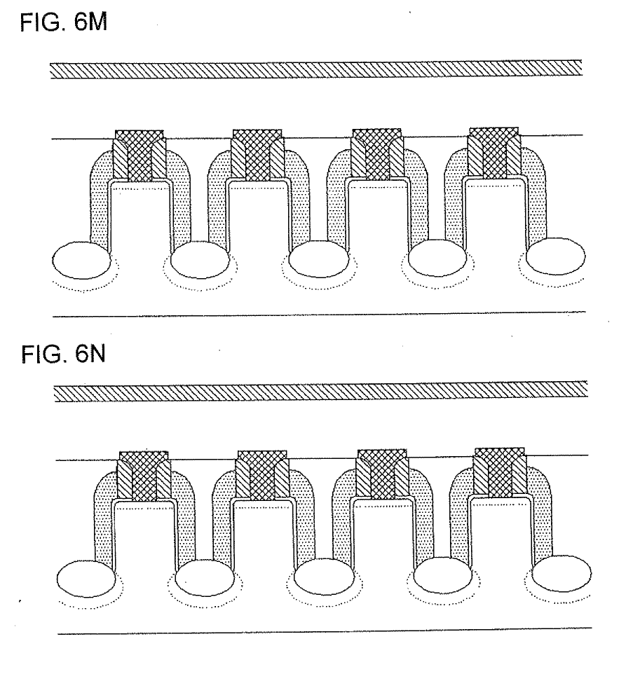

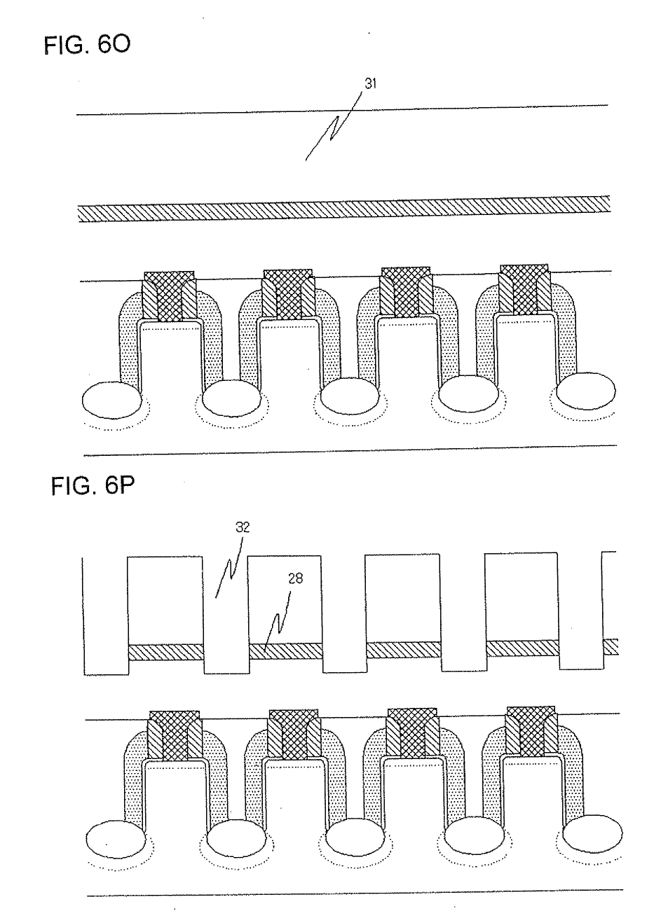

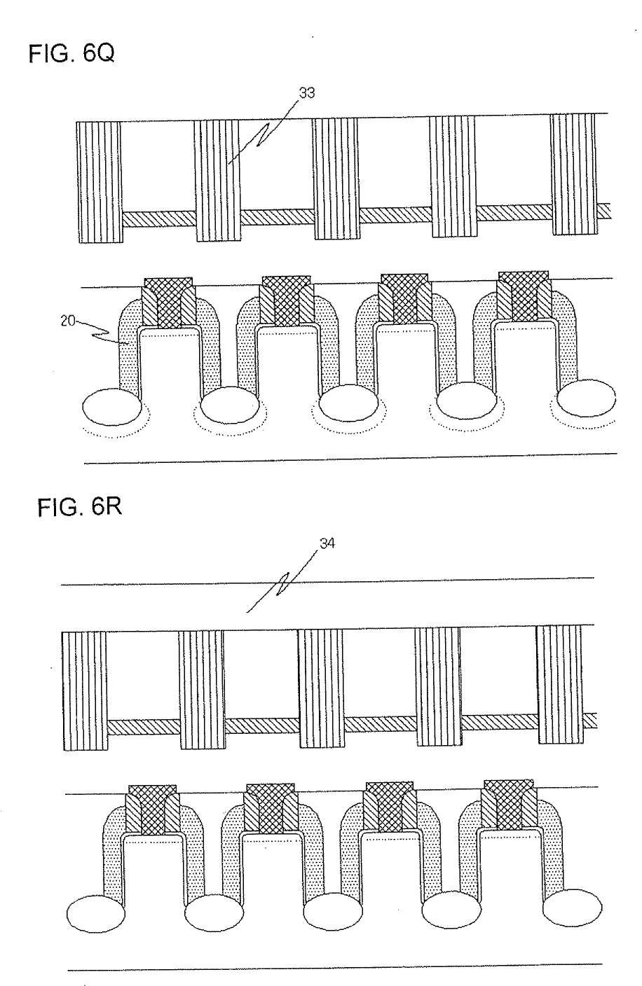

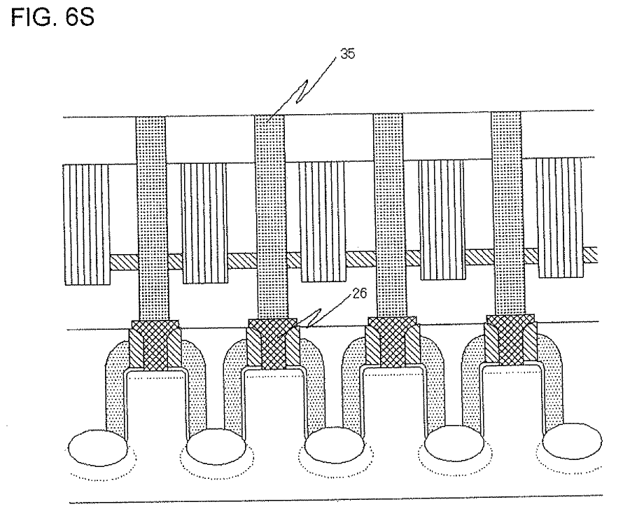

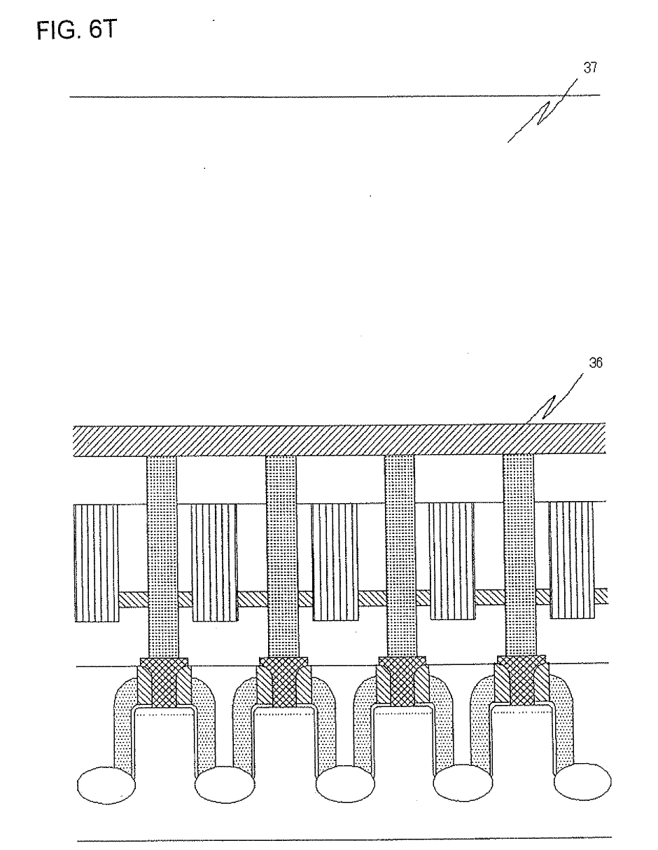

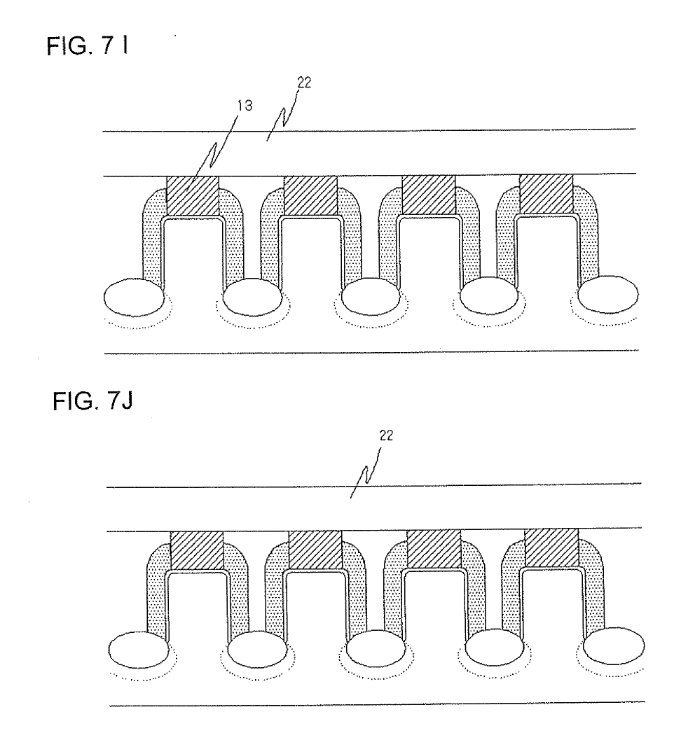

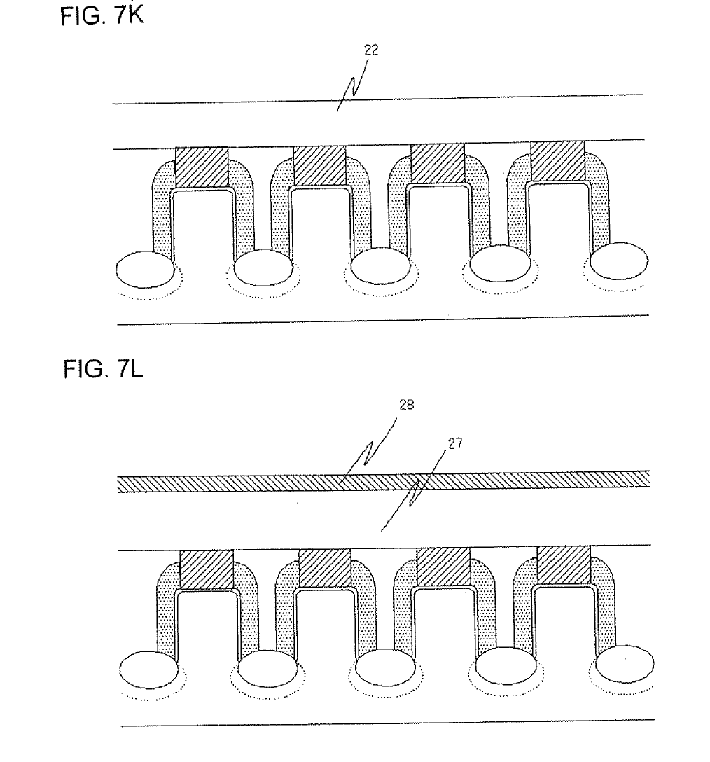

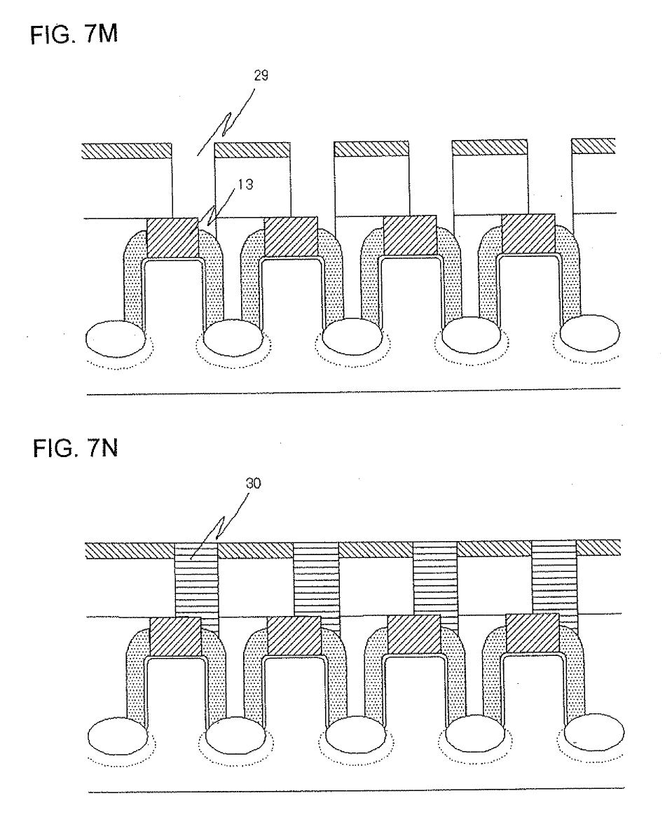

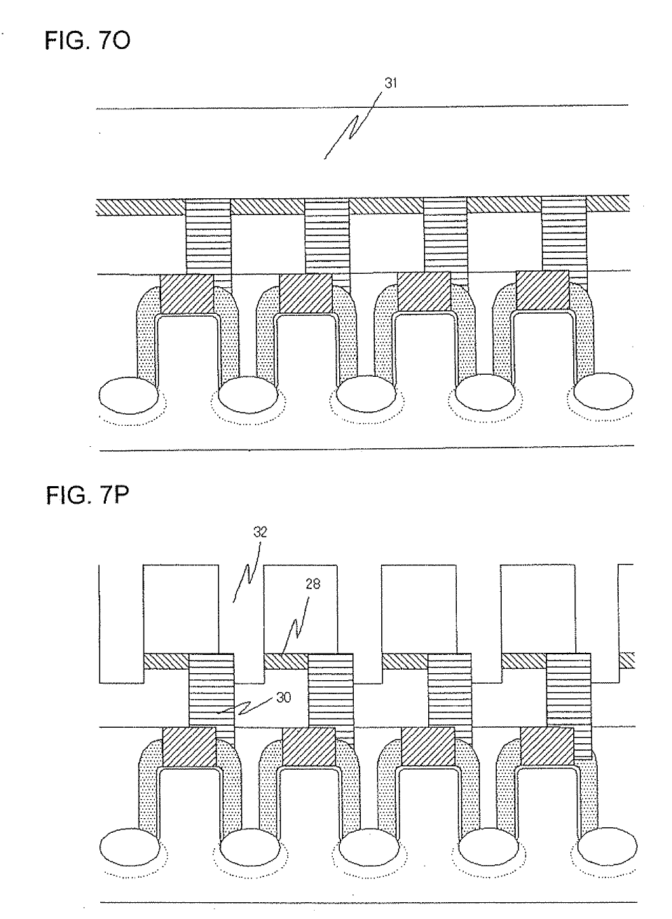

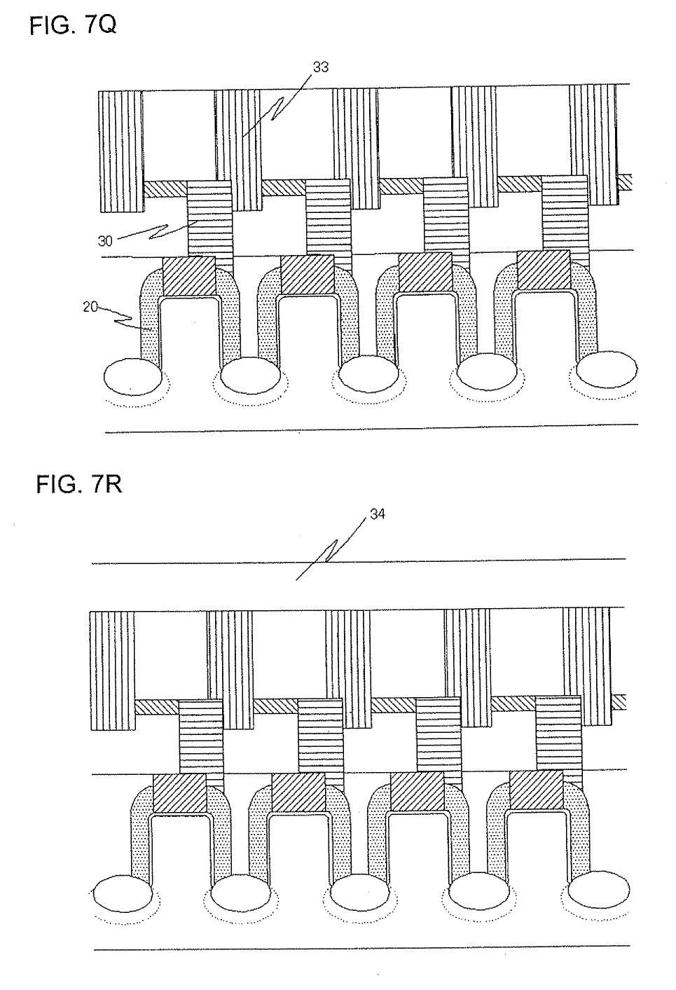

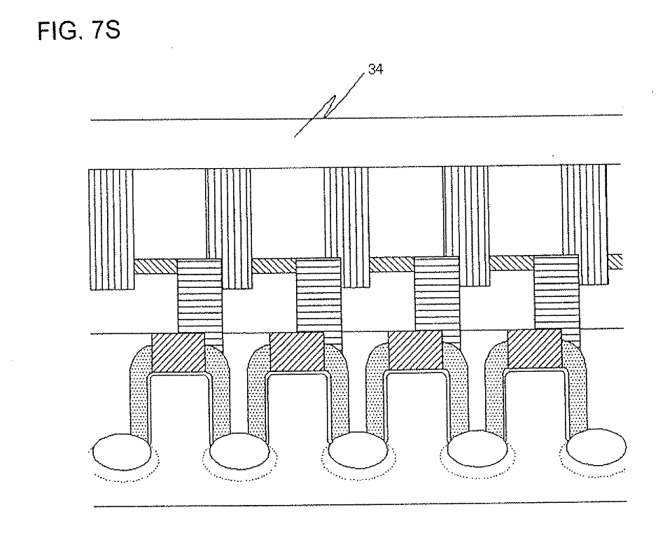

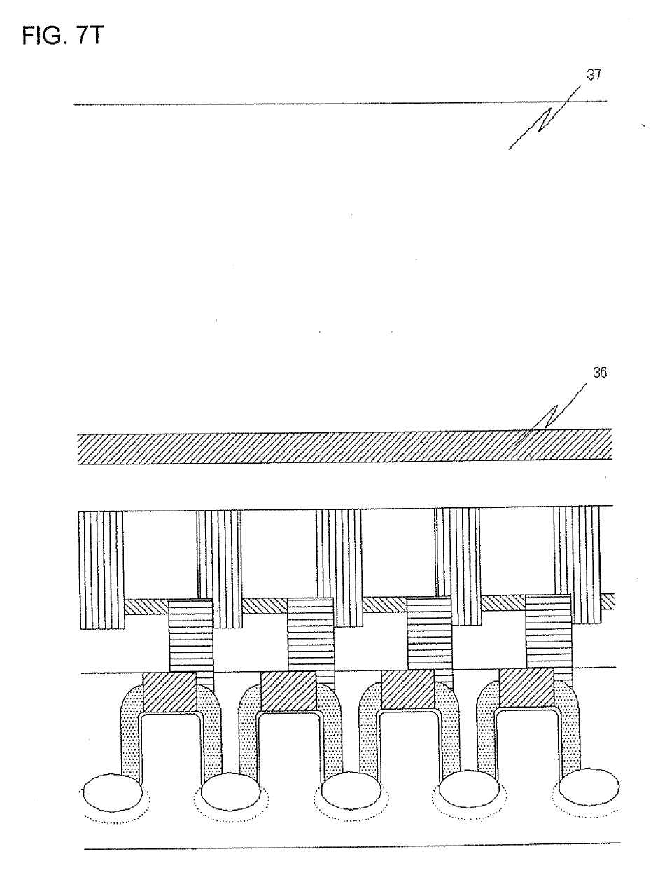

Next, one example of a method for manufacturing a semiconductor memory device according to the present exemplary embodiment will be described with reference to the accompanying drawings. A portion corresponding to the cross-section of a cell array portion as viewed along the line X1-X1 of FIG. 1 will be described by referring to FIGS. 6A to 6T in the order of steps. Likewise, a portion corresponding to the cross-section of a word-shunt portion as viewed along the line X2-X2 will be described by referring to FIGS. 7I to 7T in the order of steps. Peripheral circuits other than the cell array portion and the word-shunt portion can be fabricated according to usual methods and, therefore, their drawings will be omitted and not described. In addition, since the cell array portion and the word-shunt portion are fabricated using the same steps partway through the whole process, the same steps will only be described with respect to the cell array portion and will not be described with respect to the word-shunt portion.

First, bit lines denoted by reference numeral 3 and 4 in FIG. 1 are formed. The bit lines are formed below the word line (gate electrode) 20, as shown by reference numeral 51 in the cross-section of FIG. 4 as viewed along the line Y1-Y1 of FIG. 1 or in the cross-section of FIG. 5 as viewed along the line Y2-Y2 of FIG. 1. These bit lines are connected to diffusion layers 52 which function as drains.

Such bit lines as described above can be formed in the following way: First, a trench is formed in the silicon substrate 11 prior to forming the pillar 14. Then, an insulating film 50 is formed in the trench by means of oxidization and/or CVD. Using a lithography technique and an etching technique, part of the insulating film 50 on one of mutually opposed side surfaces within the trench is removed. The bit lines and the diffusion layer 52 will be connected at a part from where the insulating film has been removed. Next, the bit lines are formed by burying impurity-containing polysilicon in this trench. After that, an oxide film 17 is formed by oxidizing the upper portion of the impurity-containing polysilicon within the trench. The diffusion layer 52 is formed as the result of an impurity contained in the polysilicon within the trench being thermally diffused by a later-performed heat treatment.

Next, as shown in FIG. 6A, an oxide film 12 is formed on the silicon substrate 11 to a thickness of 6 nm and a mask nitride film 13 is also formed thereon to a thickness of 120 nm.

Next, as shown in FIG. 6B, a mask nitride film 13 is formed and patterned using a usual lithography technique and dry etching technique. Using this mask nitride film as a mask, the silicon substrate is etched to a depth of approximately 150 nm to form a pillar 14 to serve as the channel of a vertical transistor. The layout of the pillar 14 at this time is as shown by portions denoted by reference numerals 1 and 2 in FIG. 1, and there is no difference between a pillar in the cell array portion and a pillar in the word-shunt portion.

Next, as shown in FIG. 6C, a nitride film is formed across the entire surface of the device being manufactured after forming an oxide film 15 on the side surface of the pillar 14 to a thickness of 5 nm. Then, the nitride film is etched back to form a 15 nm-thick sidewall nitride film 16.

Next, as shown in FIG. 6D, an oxidation treatment is performed to form an oxide film 17 in a silicon-exposed portion between pillars to a thickness of 30 nm. At this time, the pillar 14 is not oxidized since the nitride film is formed on the side surface and upper surface of the pillar.

Then, as shown in FIG. 6D, an impurity, such as arsenic, is implanted to form a lower diffusion layer 18 in the lower portion of the side surface of the pillar 14. At this time, the mask nitride film 13 is formed on the upper surface of the pillar and the thickness of the mask nitride film is as large as approximately 100 nm, sufficiently larger than 30 nm which is the thickness of the oxide film 17 located between pillars. Thus, no diffusion layer is formed in the upper portion of the pillar.

Next, as shown in FIG. 6E, the sidewall nitride film 16 and the lateral oxide film 15 are removed. The sidewall nitride film 16 can be removed by means of usual wet etching using a mixed solution of fluorinated acid and phosphoric acid, while adjusting an etching time so as to leave over the mask nitride film 13. The lateral oxide film 15 can be removed by means of usual wet etching using fluorinated acid.

Next, as shown in FIG. 6F, a gate insulating film 19 is formed on the side surface of the pillar 14. In a case where a silicon dioxide film is formed as the gate insulating film, the thickness of the silicon dioxide film can be set to approximately 6 nm.

Then, as shown in FIG. 6F, impurity-containing polysilicon to serve as a gate electrode is film-formed across the entire surface of the device being manufactured to a thickness of 20 nm and is etched back across the entire surface, to form a gate electrode 20 on the side surface of each pillar.

The film thickness of this gate electrode is determined according to the layout of the pillars. As shown in FIG. 1, an inter-pillar spacing 10A in the longitudinal direction of word lines and an inter-pillar spacing 10B in the longitudinal direction of bit lines differ from each other, and the spacing in the longitudinal direction of word lines is set shorter. Gate electrodes are connected along the longitudinal direction of word lines in which the inter-pillar spacing is shorter and thus the word lines are formed. The gate electrodes must be prevented from being connected to each other in the longitudinal direction of bit lines. That is, the film thickness of the gate electrodes is set so that a value twice the film thickness of a gate electrode on the side surface of a pillar is not smaller than the inter-pillar spacing 10A in the longitudinal direction of word lines but smaller than the inter-pillar spacing 10B in the longitudinal direction of bit lines.

Next, as shown in FIG. 6G, a first interlayer insulating film 21 is formed.

Next, as shown in FIG. 6H, the first interlayer insulating film 21 is planarized using a chemical mechanical polishing (CMP) technique, so that the mask nitride film 13 is exposed. Then, a mask oxide film 22 is formed to a thickness of approximately 100 nm.

The structures of the cell array portion and the word-shunt portion formed up to this step are the same.

Next, as shown in FIG. 6I, the mask oxide film 22 is removed using a usual lithography technique and etching technique in the cell array portion, and then only the mask nitride film 13 is selectively removed to form an opening 23 directly above a pillar. After performing an oxidation treatment, an impurity, such as phosphorous, is implanted from this opening 23 to the upper portion of the pillar, to form a first upper diffusion layer 24. At this time, as shown in FIG. 7I, the mask oxide film 22 is left over in the word-shunt portion and, therefore, the mask nitride film 13 covered with the mask oxide film 22 remains as is.

Next, as shown in FIG. 6J, a nitride film is formed across the entire surface of the device being manufactured, and then etched back to form a sidewall nitride film 25 to a thickness of approximately 10 nm. In a process of forming this sidewall nitride film, the oxide film on the upper surface of each pillar is also removed so that the upper surface of each pillar is exposed. This sidewall nitride film has the functions of forming the LDD (Lightly Doped Drain) structure of a transistor and of ensuring insulation between a capacitive contact to be formed later and a gate electrode. At this time, as shown in FIG. 7J, the sidewall nitride film is not formed in the word-shunt portion and, therefore, the structure after the preceding step (FIG. 7I) is maintained under the mask oxide film 22.

Next, as shown in FIG. 6K, a silicon plug layer 26 is selectively formed on the upper surface of each pillar using a selective epitaxial growth method. After that, an impurity, such as arsenic, is ion-implanted to turn the silicon plug layer into an n-type electrical conductor, so that there is formed a second upper diffusion layer in electrical contact with the first upper diffusion layer 24 formed on the upper surface of the pillar. At this time, silicon does not grow in the word-shunt portion since the mask oxide film 22 remains as is on the upper surface, as shown in FIG. 7K. Thus, the structure after the preceding step (FIGS. 7I and 7J) is maintained.

Next, as shown in FIGS. 6L and 7L, a second interlayer insulating film 27 is formed. In FIG. 7L showing a cross-section of the word-shunt portion, the second interlayer insulating film 27 is formed on the mask nitride film 13. Since the mask oxide film 22 is formed of an insulating film the same in type as the second interlayer insulating film and serving as an interlayer insulating film, the mask oxide film 22 is integrated into the second interlayer insulating film and is illustrated as the second interlayer insulating film 27.

Then, as shown in FIGS. 6L and 7L, a first stopper nitride film 28 is formed on the second interlayer insulating film 27 to a thickness of approximately 50 nm.

Next, as shown in FIG. 7M, a word-shunt contact hole 29 is formed in the word-shunt portion. This word-shunt contact hole 29 corresponds to reference numeral 9 in FIG. 1 and, as shown in FIG. 1, is formed only in the word-shunt portion and not formed in the cell array portion. When forming this word-shunt contact hole 29, the first stopper nitride film 28 is patterned using a usual lithography technique and dry etching technique. Then, etching is performed using this patterned nitride film as a mask, i.e., under the condition that a sufficiently high selection ratio is ensured with respect to the nitride film, thereby exposing and leaving over the mask nitride film 13 and exposing the gate electrode 20 within the hole. At this time, as shown in FIG. 6M, no word-shunt contact holes are formed in the cell array portion and, therefore, the structure after the preceding step (FIG. 6L) remains as is.

Next, as shown in FIG. 7N, a word-shunt contact plug 30 made of W/TiN/Ti is formed in the word-shunt contact hole 29 in the word-shunt portion. At this time, the word-shunt contact plug is not formed in the cell array portion, as shown in FIG. 6N, and, therefore, the structure after the preceding step (FIGS. 6L and 6M)) remains as is.

Next, as shown in FIGS. 6O and 7O, a third interlayer insulating film 31 is formed.

Next, as shown in FIGS. 6P and 7P, a trench 32 for forming the word-shunt interconnect is formed using a usual lithography technique and dry etching technique. The depth of this trench is controlled by utilizing the first stopper nitride film 28. In the word-shunt portion, the trench is formed so that the word-shunt contact plug 30 is exposed, as shown in FIG. 7P.

Next, as shown in FIGS. 6Q and 7Q, W/TiN is buried in the trench 32 to form a word-shunt interconnect 33. At this time, the word-shunt interconnect 33 is in contact with the word-shunt contact plug 30, and thus electrically connecting with the gate electrode (word line) 20 below the contact plug in the word-shunt portion.

Next, as shown in FIGS. 6R and 7R, a fourth interlayer insulating film 34 is formed.

Next, as shown in FIG. 6S, a capacitive contact hole is formed immediately above each pillar in the cell array portion using a usual lithography technique and dry etching technique, so as to reach the silicon plug layer 26. Then, W/TiN/Ti is buried in this hole to form a capacitive contact plug 35. At this time, the capacitive contact plug is not formed in the word-shunt portion, as shown in FIG. 7S, and, therefore, the structure after the preceding step (FIG. 7R) remains as is.

Next, as shown in FIGS. 6T and 7T, a second stopper nitride film 36 and a cylinder interlayer insulating film 37 are formed.

Next, as shown in FIGS. 2 and 3, a deep hole for forming a cell capacitor is formed using a usual lithography technique and dry etching technique and a capacitive lower electrode 38, a capacitive insulating film 39 and a capacitive upper electrode 40 are formed in the hole, thereby completing a DRAM. In the formation of the deep hole for forming the cell capacitor, the depth of the hole can be controlled by utilizing the second stopper nitride film 36. In the cell array portion, the hole is formed so that the capacitive contact plug 35 is exposed in the bottom of the hole. At this time, the cell capacitor is formed also in the word-shunt portion, as shown in FIG. 3.

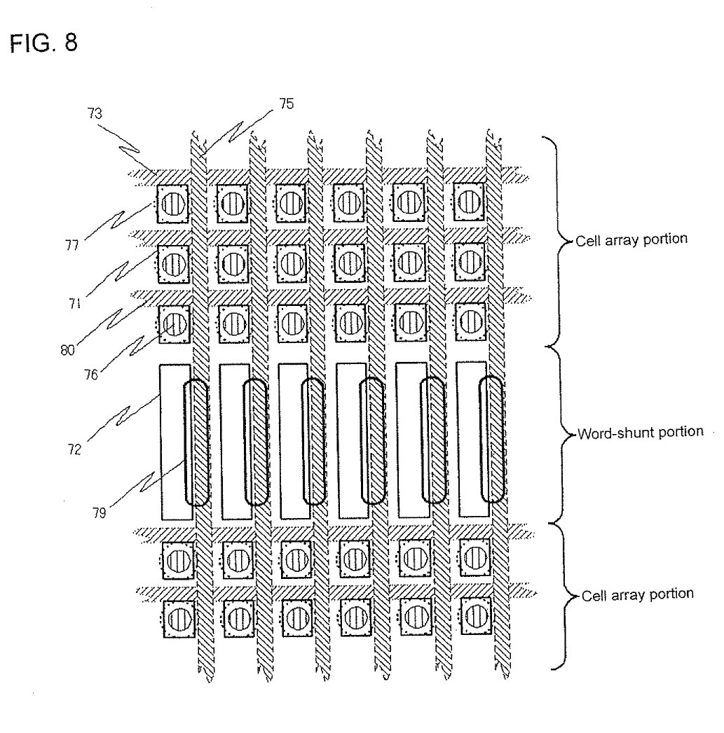

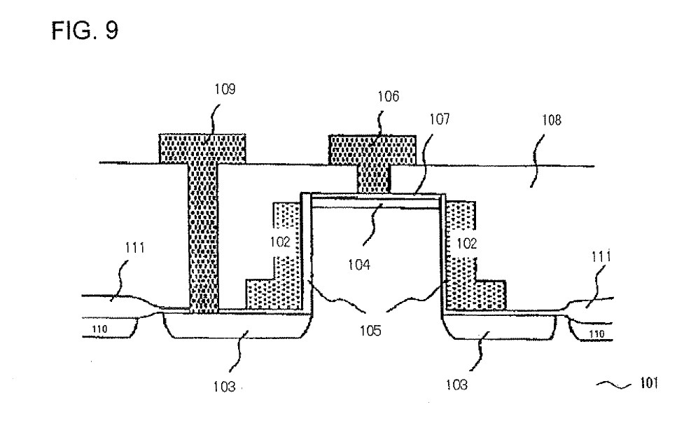

FIG. 8 illustrates, as a reference example, a layout of a memory cell array different in the structure of the word-shunt portion from that of the above-described exemplary embodiment.

This structure includes cell array portions and a word-shunt portion provided between the cell array portions in which memory cells containing capacitors and vertical transistors having pillars 71 are located.

In the word-shunt portion, word lines (not illustrated) constituting the gate electrodes of the cell transistors and word-shunt interconnects 75 provided on the upper-layer side of the word lines are connected at word-shunt contacts 79. While the pitch of the word-shunt contacts 79 is the same as the pitch of the cells, each contact 79 has a vertically-long planar shape since the contact area needs to be increased from the viewpoint of reducing contact resistance. In addition, vertically-long pillars 72 slightly longer than the length of these word-shunt contacts 79 in the longitudinal direction thereof are provided in this word-shunt portion. In the word-shunt portion, a laminated structure is formed by the word lines covering the side surfaces of the pillars 72, the word-shunt interconnects 75 provided on the upper-layer side of the word lines and the word-shunt contacts 79 connecting these word-shunt interconnects and the word lines. However, any other constituent elements (cylindrical capacitors 77, capacitive contacts 76, and bit lines 73) for composing the cell array portions are not formed in the word-shunt portion.

The memory cell array having such a word-shunt portion as described above has a defect in the repeatability of memory cell arrangement, and is accordingly likely to differ in size between the end and the central part thereof at the time of processing. Even if the cell array portion can be formed so as to be almost the same in size at the end and at the central part thereof, it is not possible to obtain a cell array portion which is electrically the same at both of these parts. Referring to a bit line 80 at an end of the cell array portion, it is understood that bit lines 73 exist on both sides of a pillar 71 at the central part of the cell array portion, whereas a bit line exists only on one side of the pillar at the end of the cell array portion. Consequently, bit-line capacitance greatly differs between the end and the central part. If an interelement spacing is small, the same holds true for the pillar 71 and capacitor 77 and, thus, element-to-element capacitance differs between the end and the central part of the cell array portion. In a DRAM in which a small amount of electric charge is accumulated in a cell capacitor Cs and a signal is read based on a balance with the capacitance of a writing/reading interconnect, any change in capacitance, resistance or the like causes a change in a timing for reading/writing the signal and leads to false operation. Consequently, even if the end of the cell array portion can be fabricated into almost the same shape as the central part thereof, cells at the end of the cell array portion cannot be used as DRAM cells for reasons of electrical imbalance. Thus, the cells are used as dummy cells which are merely laid out but do not operate. At present, two to three cells from the end of the cell array portion need to be used as dummy cells and, therefore, the area of the cell array portion increases by as much. That is, word-shunt portions needs to be located essentially and plurally from the viewpoint of reducing word-line resistance, and accordingly, the number of ends of the cell array portions increases depending on the layout thereof, thus increasing an area for dummy cells to be located at the ends of the cell array portion, in addition to an area required for the word-shunt portions themselves.

In comparison to such a structure as shown in FIG. 8, according to the exemplary embodiment of the present invention, word lines are formed into a hierarchical structure in order to achieve resistance reductions, and further, the layout of word-shunt portions, which have become necessary as the result of forming the word lines into the hierarchical structure, is made almost the same as the layout of the cell array portions. Consequently, the repeatability of memory cell disposition is not impaired, thus eliminating the need for dummy cells to be located at the ends of the cell array portion. That is, according to the exemplary embodiment of the present invention, it is possible to achieve high integration, while still maintaining the satisfactory operation of a memory.

It is apparent that the present invention is not limited to the above embodiments, but may be modified and changed without departing from the scope and spirit of the invention.

What is claimed is:

1. A semiconductor memory device, comprising:
first word lines located along a first direction;
second word lines provided along the first direction on the upper-layer side of the first word lines, each of the second word lines being electrically connected to a corresponding one of the first word lines;
bit lines located along a second direction intersecting with the first direction; and
memory cells located at intersections of the first word lines and the bit lines, each of the memory cells comprising a capacitor and a transistor including a source connected to the capacitor, a gate connected to one of the first word lines, and a drain connected to one of the bit lines;
wherein the transistor comprises:
a semiconductor pillar protruding upwardly with respect to a principal surface of a semiconductor substrate;
a gate insulating film formed on a side surface of the semiconductor pillar;
a gate electrode formed so as to cover the side surface of the semiconductor pillar through the gate insulating film;
an upper diffusion layer formed in a upper portion of the semiconductor pillar; and
a lower diffusion layer formed in a part of the semiconductor substrate below the side surface of the semiconductor pillar;
the capacitor is provided immediately above the semiconductor pillar of the corresponding transistor, the capacitor comprising an upper electrode, a dielectric film and a lower electrode connected to the upper diffusion layer of the semiconductor pillar through a first conductive plug; and
the semiconductor memory device comprises:
a first cell array portion wherein first cells are arrayed, each of the first cells including the transistor and the capacitor; and
a second cell array portion wherein second cells, the first word lines and the bit lines are located in the same layout as the first cell array portion, each of the second cells including the same transistor structure containing a semiconductor pillar, a gate insulating film and a gate electrode as the first cells, and including the same capacitor structure containing a lower electrode, a dielectric film and an upper electrode as the first cells, and wherein second conductive plugs are provided, each of the second conductive plugs connecting one of the first word lines and a corresponding one of the second word lines.

2. The semiconductor memory device according to claim 1, wherein an insulating film is interposed between the semiconductor pillars and the lower electrodes within the second cells such that the second cells do not operate as memory cells.

3. The semiconductor memory device according to claim 1, wherein each of the second conductive plugs extends across two or more of the second cells located along the first direction in the second cell array portion.

4. The semiconductor memory device according to claim 1, wherein each of the second conductive plugs is located such that the second conductive plug overlaps with a corresponding one of the semiconductor pillars in the second cell array portion.

5. The semiconductor memory device according to claim 1, wherein each of the second word lines is located on the lower-layer side of the capacitors such that the second word line passes through between the first conductive plugs of the first cells adjacent to each other in the second direction.

6. The semiconductor memory device according to claim 1, wherein the first word lines are formed of an impurity-containing polysilicon, and the second word lines are formed of a metal-containing material having a resistivity lower than that of the first word lines.

7. The semiconductor memory device according to claim 1, wherein the bit lines intersect with the first word lines on the lower-layer side of the first word lines.

8. A semiconductor memory device, comprising;
first word lines located along a first direction;
second word lines provided along the first direction above the first word lines, each of the second word lines being electrically connected to a corresponding one of the first word lines;
bit lines; and
cells located at intersections of the first word lines and the bit lines, each of cells comprising a transistor structure and a capacitor structure;
wherein the semiconductor memory device comprises:
a first cell array portion wherein each of the cells is formed such that the cell is a memory cell; and
a second cell array portion wherein the transistor structure is insulated from the capacitor structure in each of the cells such that the cell is a dummy cell, and wherein conductive plugs are provided, each of the conductive plugs connecting one of the first word lines and a corresponding one of the second word lines.

9. The semiconductor memory device according to claim 8, wherein the transistor structure comprises:
a semiconductor pillar protruding upwardly with respect to a principal surface of a semiconductor substrate;
a gate insulating film formed on a side surface of the semiconductor pillar;
a gate electrode formed so as to cover the side surface of the semiconductor pillar through the gate insulating film;
an upper diffusion layer formed in a upper portion of the semiconductor pillar; and
a lower diffusion layer formed in a part of the semiconductor substrate below the side surface of the semiconductor pillar.

10. A semiconductor memory device, comprising:
a vertical transistors disposed at a memory cell portion and a word-shunt portion;
first word lines connected to each of the vertical transistors at the memory cell portion and the word-shunt portion; and
second word lines disposed at the memory cell portion and the word-shunt portion, provided along the direction of the first word lines, each of the second word lines being electrically connected to a associating one of the first word lines at the word-shunt portion.

11. The semiconductor memory device according to claim 10, wherein the vertical transistor comprising:
a semiconductor pillar; and
a gate electrode disposed around the pillar with an intervention of a gate insulating film formed on the pillar, wherein the gate electrode is a part of the first word line.

12. The semiconductor memory device according to claim 11, further comprises capacitors, each of the capacitors being connected to a associating one of the vertical transistors at the memory cell portion.
